(19) United States
(12) Patent Application Publication
(10) Pub. No.: US 2019/0187733 A1
(43) Pub. Date: Jun. 20, 2019

(54) HIGH-VOLTAGE, HIGH-SPEED GaN DRIVER CIRCUIT

(71) Applicant: NORTHROP GRUMMAN SYSTEMS CORPORATION, Falls Church, VA (US)

(72) Inventors: Paul L. Rodgers, Solana Beach, CA (US); Timothy R. LaRocca, Torrance, CA (US)

(21) Appl. No.: 15/842,193

(22) Filed: Dec. 14, 2017

(51) Int. Cl. G05F 1/445; H03K 17/0812

(52) U.S. Cl. CPC G05F 1/445; H03K 17/08122

(57) ABSTRACT

A high-voltage, high-speed driver circuit that includes a source amplifier having an amplifying FET device with a drain terminal, a gate terminal and a source terminal, where the amplifying FET device receiving a control signal at its gate terminal and outputs an amplified control signal at its drain terminal. The driver circuit also includes an active load having a self-biasing load FET device with a drain terminal, a gate terminal and a source terminal, where the drain terminal of the load FET device is coupled to a power supply, the source terminal of the load FET device is coupled to the drain terminal of the amplifying FET device, and the source and gate terminals of the load FET device are electrically coupled together by a self-biasing line. The active load includes a load resistor provided within the self-biasing line that provides high impedance and low capacitance.

### BACKGROUND

### Field

This disclosure relates generally to a driver circuit including a source amplifier and an active load and, more particularly, to a GaN driver circuit including a source amplifier having an amplifying field effect transistor (FET) device and an active load having a self-biasing load FET device and a resistor in the self-biasing line that provides high impedance and low capacitance.

### Discussion

Power amplifiers that employ one or more FET devices for amplifying RF signals are well known in the art. Power amplifiers have many applications including, but not limited to, low noise amplifiers (LNA), intermediate frequency (IF) amplifiers, local oscillator (LO) amplifiers, etc. FET devices are well known in the transistor art and come in a variety of well known types, such a HEMT, MOSFET, MISFET, FinFET, etc., and can be integrated as horizontal devices or vertical devices. A typical FET device will include various semiconductor layers, such as silicon, gallium arsenide (GaAs), indium gallium arsenide (InGaAs), gallium nitride (GaN), indium phosphide (InP), etc. Sometimes the semiconductor layers are doped with various impurities, such as boron, to increase the population of carriers in the layer, where the higher the doping level of the layer the greater the conductivity of the particular semiconductor material. An FET device will also include a source terminal, a drain terminal and a gate terminal, where one or more of the semiconductor layers is designated a channel layer and is in a electrical contact with the source and drain terminals. An electrical potential provided to the source terminal allows electrical carriers, either N-type or P-type, to flow through the channel layer to the drain terminal. An electric signal applied to the gate terminal creates an electrical field that modulates the carriers in the channel layer, where a small change in the gate voltage can cause a large variation in the population of carriers in the channel layer to change the current flow from the source terminal to the drain terminal. Some FET devices are depletion mode devices that are on with a zero volt gate bias and are off with a negative potential gate bias.

Gate driver circuits that control a gate terminal of an FET switch or other device often employ power amplifiers. For some applications, driver circuits need to be high-voltage, high-speed circuits that are able to generate a switch control signal that has very fast pulse edges, i.e., a square wave signal having a very fast rise time, and has a large voltage swing to turn the switch on and off quickly. The speed of known driver circuits can be improved for high-speed, high-voltage applications.

### SUMMARY

The present disclosure describes a high-voltage, high-speed GaN driver circuit that is operable to control a switch. The driver circuit includes a source amplifier having an amplifying FET device with a drain terminal, a gate terminal and a source terminal, where the amplifying FET device receives a square wave control signal at its gate terminal and outputs an amplified square wave control signal at its drain terminal. The driver circuit also includes an active load having a self-biasing load FET device with a drain terminal, a gate terminal and a source terminal, where the drain terminal of the load FET device is coupled to a power supply, the source terminal of the load FET device is coupled to the drain terminal of the amplifying FET device, and the source and gate terminals of the load FET device are electrically coupled together by a self-biasing line. The active load includes a load resistor provided within the self-biasing line that causes a low and high frequency response of the active load that provides high impedance and low capacitance.

Additional features of the present disclosure will become apparent from the following description and appended claims, taken in conjunction with the accompanying drawings.

### BRIEF DESCRIPTION OF THE DRAWING

FIG. 1 is a schematic diagram of a high-voltage, high-speed driver circuit including an active load and a source amplifier.

### DETAILED DESCRIPTION OF THE EMBODIMENTS

The following discussion of the embodiments of the disclosure directed to a GaN driver circuit including a self-biased active load is merely exemplary in nature, and is in no way intended to limit the invention or its applications or uses.

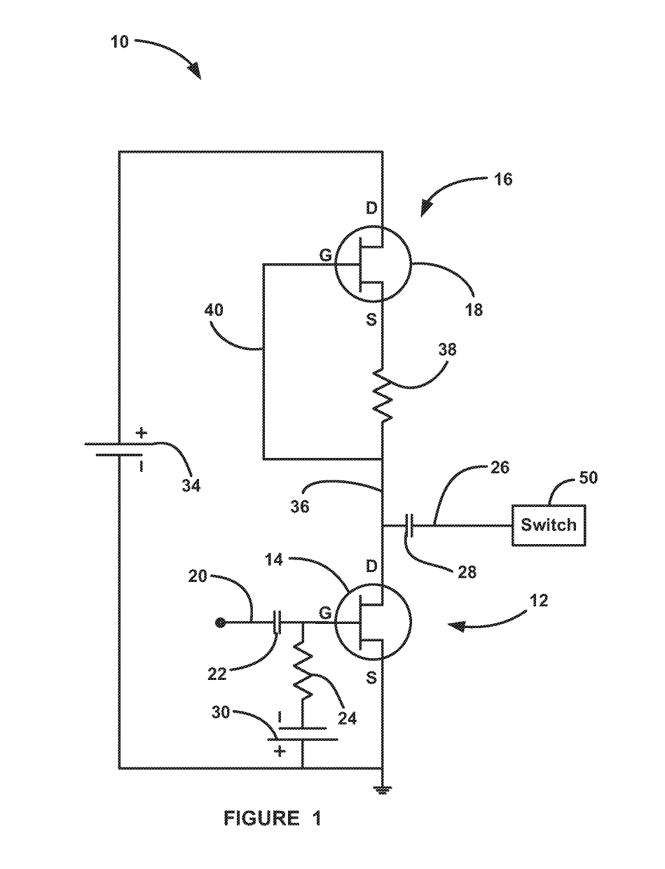

FIG. 1 is a schematic diagram of a driver circuit 10 including a source amplifier 12 having an FET device 14 and an active load 16 having a self-biased FET device 18. In this non-limiting embodiment, the FET devices 14 and 18 are N-type depletion mode GaN FET devices, and the circuit 10 controls a switch 50, such as a high impedance GaN FET switch, where the driver circuit 10 would be a gate driver circuit. However, the driver circuit 10 can control other devices, such as a second stage amplifier. Further, the amplifier 12 can be any amplifier suitable for the purposes discussed herein that may include multiple amplifier stages and may or may not include FET devices.

A control signal to be amplified is provided as a bias to the gate terminal G of the FET device 14 on line 20 through an RC circuit including a capacitor 22, a resistor 24 and a power supply 30. The control signal can be any control signal suitable for the purposes discussed herein, such as a square wave digital control signal where each square wave pulse represents a bit. An amplified output of the control signal is provided at the drain terminal D of the FET device 14 on line 26 through capacitor 28 to the switch 50, where the source terminal S of the FET device 14 is coupled to a reference potential. In one embodiment, the square wave control signal is amplified by the FET device 14 to a much larger square wave signal having fast rising and falling edges and a slew rate similar to the input control signal.

The impedance of the active load 16 multiplied by the drain current from the amplifier 12 forms the output signal. The active load 16 plus a relatively small external resistance has a minimal voltage drop so that minimal headroom and power are consumed. The drain terminal D of the FET device 18 is coupled to a power source 34 and the source terminal S of the FET device 18 is coupled to the drain terminal D of the FET device 14. The source terminal S and the gate terminal D of the FET device 18 are tied together by a self-biasing line 40 so that the FET device 18 is self-biasing, and a resistor 38 is provided in the line 40. When the control signal is low, the FET device 14 conducts because it operates in the depletion mode, and current flows through the devices 14 and 18 allowing the FET device 14 to amplify the control signal. By including the resistor 38 in the self-biasing line 40, a voltage drop is provided across the resistor 38 that provides the large voltage swings necessary to allow the FET device 14 to conduct very quickly, where the voltage drop across the resistor 38 can be properly calibrated for a certain performance by selecting a proper resistance.

By including the resistor 38 in the self-biasing line 40, the low frequency response looking into the load 16 from the line 36 provides high impedance, which provides high gain, and the high frequency response looking into the load 16 from the line 36 provides low capacitance, which provides a broad-band response and faster transitioning of the edges of the square wave, i.e., higher slew rate. Derivations of the low and high frequency responses of the active load 16 illustrating these features are provided below, where gm is the transconductance of the FET device 18, R is the resistance of the resistor 38, r₀ is the intrinsic impedance of the FET device 18, vₓ is an imaginary voltage looking into the active load 16, iₓ is an imaginary current looking into the active load 16, |vₓ/iₓ| is the impedance looking into the active load 16, v_{g} is the gate terminal voltage of the FET device 18, vₛ is the source terminal voltage of the FET device 18, v_{gs} is the gate/source terminal voltage (self-bias) of the FET device 18, Cds is the drain/source terminal capacitance of the FET device 18, and ω is angular frequency. The advantages of providing the resistor 38 in the self-biasing line 40 referred to herein is generally provided by the multiplied gmR affect.

The derivation of the low frequency response is provided in equations (1)-(5) below and shows that the resistor 38 has the effect of increasing the impedance r₀ by a gmR factor, which increases the load impedance.

$$\begin{matrix}{v}_{x} + {i}_{x} R + gm {v}_{gs} {r}_{o} = 0 & ( 1 ) \\ {v}_{x} + {i}_{x} + gm {i}_{x} R \cdot {r}_{o} = 0 & ( 2 ) \\ {v}_{x} + {i}_{x} ( R + gm R \cdot {r}_{o} ) = 0 & ( 3 ) \\ \vert \frac{{v}_{x}}{{i}_{x}} \vert = R ( 1 + gm {r}_{o} ) & ( 4 ) \\ \vert \frac{{v}_{x}}{{i}_{x}} \vert = gm R {r}_{o} + R & ( 5 )\end{matrix}$$

The derivation of the high frequency response is provided in equations (6)-(15) below and shows that the resistor 38 has the effect of reducing the capacitance Cds by a gmR factor.

$$\begin{matrix}{v}_{x} + {v}_{gs} + \frac{gm {v}_{gs}}{ω Cds} = 0 & ( 6 ) \\ {v}_{x} + {i}_{x} R + \frac{gm {v}_{gs}}{ω Cds} = 0 & ( 7 ) \\ {v}_{x} - {v}_{s} = {i}_{x} R & ( 8 ) \\ {v}_{g} - {v}_{s} = {i}_{x} R & ( 9 ) \\ {v}_{gs} = {i}_{x} R & ( 10 ) \\ {v}_{x} + {i}_{x} R + \frac{gm {i}_{x} R}{ω Cds} = 0 & ( 11 ) \\ {v}_{x} + {i}_{x} ( R + \frac{gm R}{ω Cds} ) = 0 & ( 12 ) \\ \vert \frac{{v}_{x}}{{i}_{x}} \vert = R ( 1 + \frac{gm}{ω Cds} ) & ( 13 ) \\ \frac{gm R}{ω Cds} = \frac{1}{\frac{ω Cds}{gmR}} & ( 14 ) \\ \vert \frac{{v}_{x}}{{i}_{x}} \vert = \frac{1}{ω ( \frac{Cds}{gmR} )} + R & ( 15 )\end{matrix}$$

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

1. A driver circuit comprising:
a source amplifier including an amplifying field effect transistor (FET) device having a drain terminal, a gate terminal and a source terminal, said amplifying FET device receiving a control signal at its gate terminal and outputting an amplified control signal at its drain terminal; and
an active load including a load FET device having a drain terminal, a gate terminal and a source terminal, said drain terminal of the load FET device being coupled to a power supply, said source terminal of the load FET device being coupled to the drain terminal of the amplifying FET device, and said source and gate terminals of the load FET device being electrically coupled by a self-biasing line, said active load including a load resistor provided in the self-biasing line.

2. The driver circuit according to claim 1 wherein the amplifying FET device and the load FET device are depletion mode devices.

3. The driver circuit according to claim 1 wherein the amplifying FET device and the load FET device are GaN devices.

4. The driver circuit according to claim 3 wherein the GaN devices are N-type devices.

5. The driver circuit according to claim 1 wherein the amplified control signal controls a switch.

6. The driver circuit according to claim 1 wherein the control signal is a square wave.

7. The driver circuit according to claim 1 wherein the active load has a low frequency response that provides high impedance.

8. The driver circuit according to claim 1 wherein the active load has a high frequency response that provides low capacitance.

9. A driver circuit comprising:
an amplifying sub-circuit including an input receiving a control signal and an output providing an amplified control signal; and
an active load including a field effect transistor (FET) device having a drain terminal, a gate terminal and a source terminal, said drain terminal of the FET device being coupled to a power supply, said source terminal of the FET device being coupled to the output of the amplifying sub-circuit, and said source and gate terminals of the FET device being electrically coupled by a self-biasing line, said active load including a load resistor provided in the self-biasing line.

10. The driver circuit according to claim 9 wherein the FET device is a depletion mode device.

11. The driver circuit according to claim 9 wherein the FET device is a GaN device.

12. The driver circuit according to claim 11 wherein the GaN device is an N-type device.

13. The driver circuit according to claim 9 wherein the amplified control signal controls a switch.

14. The driver circuit according to claim 9 wherein the control signal is a square wave.

15. The driver circuit according to claim 9 wherein the active load has a low frequency response that provides high impedance.

16. The driver circuit according to claim 9 wherein the active load has a high frequency response that provides low capacitance.

17. A driver circuit for controlling a switch, said circuit comprising:
a source amplifier including an amplifying field effect transistor (FET) device having a drain terminal, a gate terminal and a source terminal, said amplifying FET device receiving a square wave control signal at its gate terminal and outputting an amplified square wave control signal at its drain terminal that is sent to the switch; and
an active load including a load FET device having a drain terminal, a gate terminal and a source terminal, said drain terminal of the load FET device being coupled to a power supply, said source terminal of the load FET device being coupled to the drain terminal of the amplifying FET device, and said source and gate terminals of the load FET device being electrically coupled by a self-biasing line, said active load including a load resistor provided in the self-biasing line, wherein the active load has a low frequency response that provides high impedance and a high frequency response that provides low capacitance.

18. The driver circuit according to claim 17 wherein the amplifying FET device and the load FET device are depletion mode devices.

19. The driver circuit according to claim 17 wherein the amplifying FET device and the load FET device are GaN devices.

20. The driver circuit according to claim 19 wherein the GaN devices are N-type devices.
